(19) United States
(12) Patent Application Publication
(10) Pub. No.: US 2011/0146749 A1
(43) Pub. Date: Jun. 23, 2011

(54) INTEGRATED THIN-FILM SOLAR BATTERY

(76) Inventors: Yoshiyuki Nasuno, Osaka (JP); Tohru Takeda, Osaka (JP)

(21) Appl. No.: 13/061,204

(22) PCT Filed: Aug. 5, 2009
(86) PCT No.: PCT/JP2009/063870

§ 371 Date: Feb. 28, 2011

(30) Foreign Application Priority Data
Sep. 3, 2008 (JP) 2008-226215

(51) Int. Cl. H01L 31/05

(52) U.S. Cl. 136/244

(57) ABSTRACT

An integrated thin-film solar battery, comprising:
a string that includes a plurality of thin-film photoelectric conversion elements formed on a transparent insulating substrate and electrically connected in series to each other; and
one or more power collecting electrodes electrically jointed to the string, wherein
the thin-film photoelectric conversion elements have a first transparent electrode layer laminated on the transparent insulating substrate, a photoelectric conversion layer laminated on the first electrode layer, and a second electrode layer laminated on the photoelectric conversion layer,
the power collecting electrode is electrically jointed onto the second electrode layer of any thin-film photoelectric conversion element in the string,
the string has an element separating groove formed by removing the second electrode layer and the photoelectric conversion layer between the adjacent two thin-film photoelectric elements,
the first electrode layer of one thin-film photoelectric conversion element has an extending section whose one end crosses the element separating groove and that extends to a region of another adjacent thin-film photoelectric conversion element, and is electrically insulated from the first electrode layer of the adjacent thin-film photoelectric conversion element by one or more electrode separating line,
the second electrode layer of the one thin-film photoelectric conversion element is electrically connected to the extending section of the first electrode layer of the adjacent thin-film photoelectric conversion element via a conductive section passing through the photoelectric conversion layer,
the thin-film photoelectric conversion element jointed to the power collecting electrode is constituted so that the conductive section is arranged on at least one of an upper-stream side and a lower-stream side in a current direction of an electric current flowing through the string with respect to the power collecting electrode, and the first electrode layer just below and near the power collecting electrode is short-circuited from the second electrode layer by the one or more conductive sections.

### TECHNICAL FIELD

The present invention relates to an integrated thin-film solar battery.

### BACKGROUND ART

As a conventional technique 1, for example, FIG. 6 in Patent Document 1 discloses an integrated thin-film solar battery having a string where a plurality of thin-film photoelectric conversion elements are electrically connected in series.

In the conventional technique 1, the thin-film photoelectric conversion elements are configured so that a transparent electrode layer, a photoelectric conversion layer and a metal electrode layer are sequentially laminated on a transparent insulating substrate, and a power collecting electrode made of a metal bar is jointed onto three or more places of the metal electrode layer of the thin-film photoelectric conversion elements via a brazing filler metal.

Further, as an integrated thin-film solar battery in a conventional technique 2, FIG. 1 of Patent Document 1 discloses an integrated thin-film solar battery having the following constitution.

In this constitution, in thin-film photoelectric conversion elements that joint power collecting electrodes, metal electrode layer and photoelectric conversion layer are partially removed so that grooves are formed, and the power collecting electrodes are buried into the grooves so as to be electrically connected to the transparent electrode layer directly.

This constitution is also disclosed in FIG. 1 of Patent Document 2.

In the integrated thin-film solar batteries in the conventional techniques 1 and 2 where the power collecting electrodes are jointed to the three or more thin-film photoelectric conversion elements, the plurality of thin-film photoelectric conversion elements between the power collecting electrode on one end side and the intermediate power collecting electrode are connected in series so as to form one series-connected string. Further, the series-connected strings adjacent in a series-connecting direction are constituted so that their current directions are opposite to each other.

Further, as a conventional technique 3, FIG. 1 in Patent Document 3 discloses an integrated thin-film solar battery having a constitution such that a power collecting electrode is jointed to only a metal electrode layer of thin-film photoelectric conversion elements on both ends in the serial-connecting direction.

Further, as a conventional technique 4, FIG. 3 in Patent Document 3 discloses an integrated thin-film solar battery having a constitution such that a power collecting electrode is jointed to a metal electrode layer of thin-film photoelectric conversion elements on both ends in a serial-connecting direction and a metal electrode layer of one or more thin-film photoelectric conversion elements between the thin-film photoelectric conversion elements on the both ends.

### PRIOR ART DOCUMENTS

### Patent Documents

Patent Document 1: Japanese Patent Application Laid-Open No. 2005-353767
Patent Document 2: Japanese Patent Application Laid-Open No. 2000-49369
Patent Document 3: Japanese Patent Application Laid-Open No. 2001-68713

### DISCLOSURE OF THE INVENTION

### Problem to be Solved by the Invention

In the integrated thin-film solar battery of the conventional technique 1, when the power collecting electrode is jointed onto the metal electrode layer of the thin-film photoelectric conversion element via the brazing filler metal, since a film thickness of the thin-film photoelectric conversion elements is 200 to 5000 nm that is thin, the photoelectric conversion layer between the metal electrode layer and the transparent electrode layer is occasionally short-circuited halfway due to a pressure generated by pressing the power collecting electrode onto a surface of the metal electrode layer.

In this case, since the photoelectric conversion layer just below the power collecting electrode has a normal photoelectric converting function, an electric power generated from the photoelectric conversion layer is consumed on the short-circuited portion so that a heat is locally generated. The local heat generation causes, far example, substrate cracking, film peeling, electrode damage and dropping of the power collecting electrode.

In addition to this case, since the photoelectric conversion layer just below the power collecting electrode is not sufficiently separated from another adjacent photoelectric conversion layer in the series-connecting direction, when the metal electrode layer of one thin-film photoelectric conversion element insufficiently contacts with the transparent electrode layer of another adjacent thin-film photoelectric conversion element, a large electric current flow intensively to the short-circuited places in the photoelectric conversion layer, thereby causing more heat generation.

The “short-circuit halfway” means that since a power resistance is larger than that in a normal electric short circuit (a range of the electric resistance: 10 to 1000Ω), and the heat generation occurs at the time when an electric current flow.

In a case of the conventional technique 2, since the power collecting electrode is formed on the transparent electrode layer, the problem of the short circuit like the conventional technique 1 does not arise.

In a case of the conventional technique 4 in which an intermediate power collecting electrode 114 is provided in the string having the element series-connected constitution, as shown in FIGS. 12 and 13, when a short-circuited portion is present in a photoelectric conversion layer 3 just below the intermediate power collecting electrode 114, also the photoelectric conversion layer 3 might generate a heat locally. In FIGS. 12 and 13, a symbol 101 represents a transparent insulating substrate, 102 represents a transparent electrode layer, 104 represents a metal electrode layer, 104a represents a conductive section for series connection, 105 represents a thin-film photoelectric conversion element, and 106 and 107 represent a power collecting electrode.

### Means for Solving the Problem

It is an object of the present invention to provide an integrated thin-film solar battery that solves the problems of the conventional techniques and can prevent a local heat generation caused by shirt circuit in thin-film photoelectric elements.

Therefore, the present invention provides an integrated thin-film solar battery that is constituted so as to include:

a string including a plurality of thin-film photoelectric conversion elements that are formed on a transparent insulating substrate and is electrically connected in series to each other; and

one or more power collecting electrodes electrically jointed to the string, wherein

the thin-film photoelectric conversion elements have a first transparent electrode layer laminated on the transparent insulating substrate, a photoelectric conversion layer laminated on the first electrode layer, and a second electrode layer laminated on the photoelectric conversion layer,

the power collecting electrode is electrically connected onto the second electrode layer of any thin-film photoelectric conversion element in the string,

the string has an element separating groove that is formed by removing the second electrode layer and the photoelectric conversion layer between the adjacent two thin-film photoelectric conversion elements,

the first electrode layer of one thin-film photoelectric conversion element has an extended section whose one end crosses the element separating groove and that extends to a region of another adjacent thin-film photoelectric conversion element, and is electrically insulated from the first electrode layer of the adjacent thin-film photoelectric conversion element by one or more electrode separating lines,

the second electrode layer of one thin-film photoelectric conversion element is electrically connected to the extended section of the first electrode layer of adjacent thin-film photoelectric conversion element via a conductive section passing through the photoelectric conversion layer,

the thin-film photoelectric conversion element jointed to the power collecting electrode is constituted so that the conductive section is arranged on at least one of an upper-stream side and a lower-stream side in a current direction of an electric current flowing through the string with respect to the power collecting electrode, and the first electrode layers just below and near the power collecting electrode is short-circuited from the second electrode layer by one or more conductive sections.

### EFFECT OF THE INVENTION

In the integrated thin-film solar battery of the present invention, as described above, on the thin-film photoelectric conversion element jointed to the power collecting electrode, the conductive section is arranged on at least one of the upper-stream side and the lower-stream side in the current direction of the current flowing through the string with respect to the power collecting electrode. Further, the electrode separating line is provided on at least one of the upper-stream side and the lower-stream side with respect to the power collecting electrode or is not provided, and the first electrode layer just below and near the power collecting electrode is short-circuited from the second electrode layer at the one or more conductive sections.

Therefore, even if a halfway short circuit occurs in the photoelectric conversion layer just below the power collecting electrode due to a pressure or a heat at the time of jointing the power collecting electrode onto any thin-film photoelectric conversion element in the string, an electric current flow to the conductive section so that the electric current does not flow in the that short-circuited portion, and thus a local heat generation on the short-circuited portion is prevented.

Therefore, the integrated thin-film solar battery of the present invention can prevent occurrences of substrate cracking, film peeling, electrode damage and dropping of the power collecting electrode.

### BRIEF DESCRIPTION OF THE DRAWINGS

FIG. 1 is a plan view illustrating an integrated thin-film solar battery according to an embodiment 1 of the present invention.

FIG. 2(a) is a cross-sectional view where the integrated thin-film solar battery in FIG. 1 is cut in a series-connecting direction, FIG. 2(b) is a side view of the integrated thin-film solar battery in FIG. 1 viewed from the series-connecting direction, and FIG. 2(c) is a side view of a modified example of the integrated thin-film solar battery in FIG. 1 viewed from the series-connecting direction.

FIG. 3 is a cross-sectional view illustrating the integrated thin-film solar battery according to an embodiment 2 of the present invention, FIG. 3(a) illustrates a side of a first power collecting electrode, and FIG. 3(b) illustrates a side of a second power collecting electrode.

FIG. 4 is a cross-sectional view illustrating the integrated thin-film solar battery according to an embodiment 3 of the present invention, FIG. 4(a) illustrates a side of the first power collecting electrode, and FIG. 4(b) illustrates a side of the second power collecting electrode.

FIG. 5 is a plan view illustrating the integrated thin-film solar battery according to an embodiment 4 of the present invention.

FIG. 6 is a plan view illustrating the integrated thin-film solar battery according to an embodiment 5 of the present invention.

FIG. 7 is a cross-sectional view where the integrated thin-film solar battery in FIG. 6 is cut in the series-connecting direction.

FIG. 8 is a partial cross-sectional view illustrating the integrated thin-film solar battery according to an embodiment 6 of the present invention.

FIG. 9 is a partial cross-sectional view illustrating the integrated thin-film solar battery according to an embodiment 7 of the present invention.

FIG. 10 is a partial cross-sectional view illustrating the integrated thin-film solar battery according to an embodiment 8 of the present invention.

FIG. 11 is a partial cross-sectional view illustrating the integrated thin-film solar battery according to an embodiment 9 of the present invention.

FIG. 12 is a partial cross-sectional view illustrating a conventional integrated thin-film solar battery.

FIG. 13 is a partial cross-sectional view illustrating another conventional integrated thin-film solar battery.

### MODE FOR CARRYING OUT THE INVENTION

In the present invention, a material, a number and a joint position of a power collecting electrode, a material, a number and a forming position of a conductive section, a number, a shape, a dimension and a material of a thin-film photoelectric conversion element configuring a string, a number and an arrangement of the string, an electric connecting method of a plurality of the strings and the like are not particularly limited.

Embodiments of an integrated thin-film solar battery of the present invention are described in detail below with reference to the drawings. The modes are examples of the present invention, and the present invention is not limited to the embodiments.

### Embodiment 1

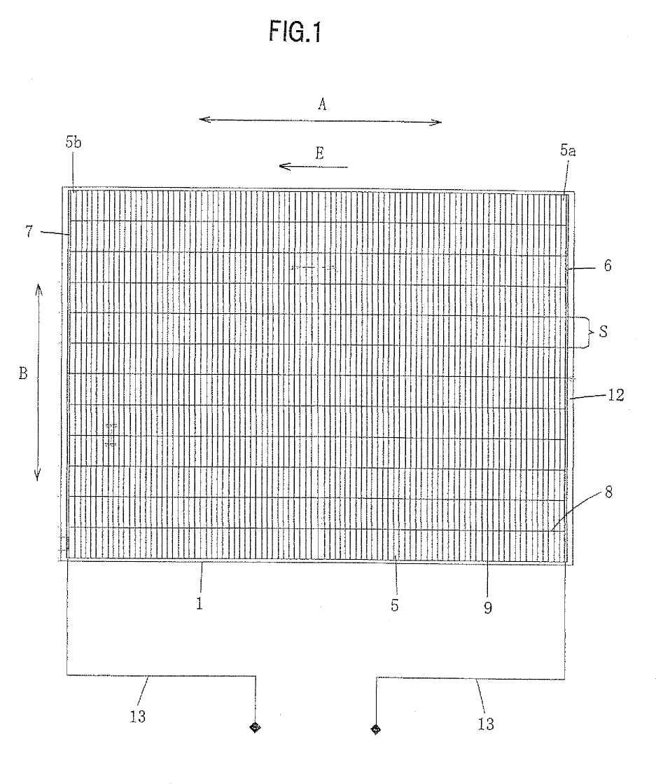

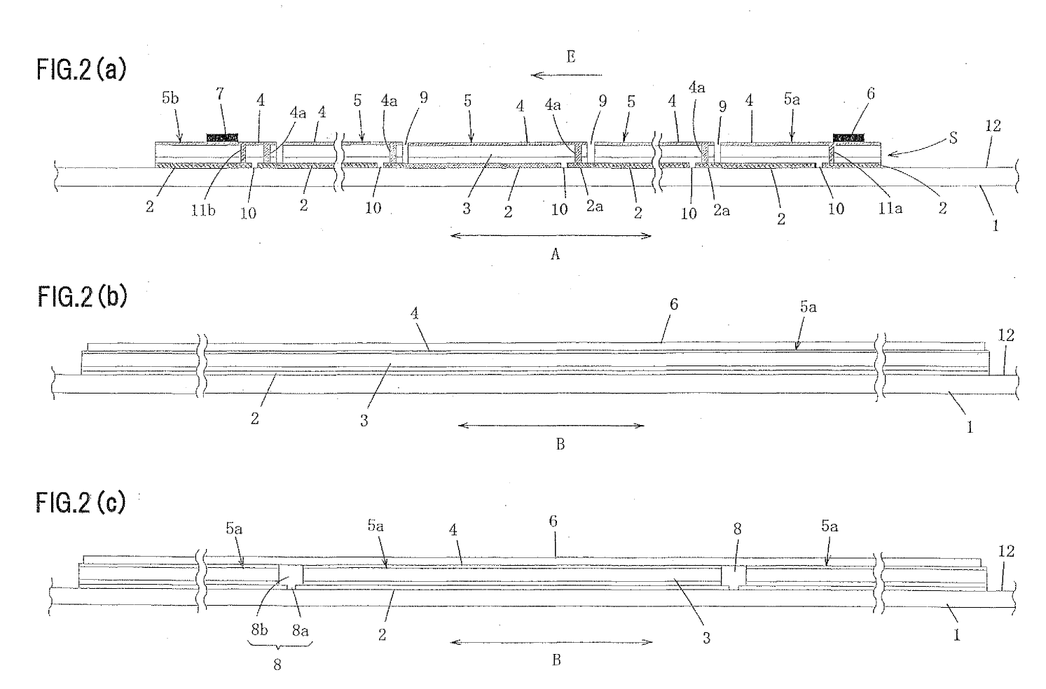

FIG. 1 is a plan view illustrating the integrated thin-film solar battery according to an embodiment 1 of the present invention. FIG. 2(a) is a cross-sectional view where the integrated thin-film solar battery in FIG. 1 is cut in a series-connecting direction, FIG. 2(b) is a side view of the integrated thin-film solar battery in FIG. 1 viewed from the series-connecting direction, and FIG. 2(c) is a side view of a modified example of the integrated thin-film solar battery in FIG. 1 viewed from the series-connecting direction.

In FIGS. 1 and 2(a), an arrow E represents a flowing direction of an electric current (current direction), and when simple description of “an upper stream” or “a lower stream” in this specification means an upper stream or a lower stream in the current direction.

In FIGS. 1 and 2(a), an arrow A represents the series-connecting direction, and means a direction where a plurality of thin-film photoelectric conversion elements that are connected in series is arranged.

In FIGS. 1 and 2(a), an arrow B represents a direction that is perpendicular to the series-connecting direction.

This integrated thin-film solar battery includes a square transparent insulating substrate 1, a string S including a plurality of thin-film photoelectric conversion elements 5 that are formed on the insulating substrate 1 and is electrically connected in series to each other, one first power collecting electrode 6 and one second power collecting electrode 7 that are electrically jointed onto a second electrode layer 4 of thin-film photoelectric conversion elements 5a and 5b on both ends of the series-connecting direction A in the string S via brazing filler metal.

The thin-film photoelectric conversion elements 5 are constituted so that a transparent first electrode layer 2, a photoelectric conversion layer 3 and the second electrode layer 4 are laminated on the insulating substrate 1 in this order.

As the first and second power collecting electrodes 6 and 7, for example, a copper line, a solder plating copper line or the like is used.

Further, in this solar battery, a plurality of the strings S (in this case, 12) are arranged on the insulating substrate 1 in the direction B perpendicular to the series-connecting direction via a plurality of string separating grooves 8 (in this case, 11) extending to the series-connecting direction A.

Hereinafter, in some cases, “the integrated thin-film solar battery” is abbreviated as “the solar battery”, and “the thin-film photoelectric conversion element” is abbreviated as “the cell”.

<String>

As shown in FIGS. 1 and 2(a), the string S has an element separating groove 9 that is formed by removing the second electrode layer 4 and the photoelectric conversion layer 3 between the adjacent two cells (thin-film photoelectric conversion elements) 5. This element separating groove 9 extends to the arrow direction B so that the second electrode 4 and the photoelectric conversion layer 3 of the one cell 5 are electrically separated from the second electrode 4 and the photoelectric conversion layer 3 of the adjacent another cell 5.

In this string S, the first electrode layer 2 of the one cell 5 has an extending section 2a whose one end (a lower-stream side end in the current direction E) crosses the element separating groove 9 and that extends to a region of adjacent another cell 5, and is electrically insulated from the adjacent first electrode layer 2 by an electrode separating line 10.

Further, one end (upper-stream side end in the current direction E) of the second electrode layer 4 of the one cell 5 is electrically connected to the extending section 2a of the first electrode layer 2 of the adjacent cell 5 via a conductive section 4a piercing the photoelectric conversion layer 3. The conductive section 4a can be formed integrally with the second electrode layer 4 by the same step and the same material.

Further, as to the string S, the first electrode layer 2 just below and near the first and second power collecting electrodes 6 and 7 is electrically connected to the second electrode layer 4 via conductive sections 11a and 11b piercing the photoelectric conversion layer 3 in cells 5a and 5b formed with the first and second power collecting electrodes 6 and 7.

In the case of the embodiment 1, the conductive sections 11a of the cells 5a on an uppermost-stream side are arranged on the lower-stream side with respect to the first power collecting electrode 6, and the conductive sections 11b of the cells 5b on a lowermost-stream side are arranged on the upper-stream side with respect to the second power collecting electrode 7.

Further, in the cells 5a jointed to the first power collecting electrode 6 on the upper-stream side in the current direction E, the electrode separating line 10 is arranged on the lower-stream side with respect to the first power collecting electrode 6 so that a lower-stream side portion with respect to the first power collecting electrode 6 can contribute to a power generation. The cell 5a is designed with a width in the direction of the arrow A being wide so as to contribute to the power generation, but if the electrode separating line 10 is not present, the cell 5a is short-circuited by the conductive section 11a, and thus does not contribute to the power generation. For this reason, the cell 5a is provided with the electrode separating line 10 on the lower-stream side with respect to the first power collecting electrode 6.

When the cell 5a is not allowed to contribute to the power generation, the width in the direction of the arrow A is designed to be narrow, and the electrode separating line 10 does not have to be formed. However, similarly the short circuit is obtained by the conductive section 11a so that an electric current does not flow in the short-circuited portion just below the first power collecting electrode 6.

In this case, the cell 5a that does not contribute to the power generation is present as a region for jointing the first power collecting electrode 6, but in order to electrically connect the first power collecting electrode 6 to the second electrode 4 of the adjacent cell 5 on the lower-stream side via the cell 5a, the conductive section 4a and the element separating groove 9 should be formed between the cells 5 and 5a.

Therefore, as shown in FIG. 2(a), when the cell 5a is designed so as to have the portion contributing to the power generation, the first power collecting electrode 6 is jointed directly to the second electrode 4 on the power generation contributing portion, and thus it is preferable because the conductive section 4a and the element separating groove 9 between the cells 5 and 5b can be practically omitted.

Further, in the plurality of strings S, the cells 5a and 5b formed with the first and second power collecting electrodes 6 and 7 may be connected to each other integrally as shown in FIG. 2(b), or may be insulated from each other by the string separating groove 8 as shown in FIG. 2(c).

In a case of FIG. 2(b), the string separating groove 8 does not completely separate the adjacent two strings S, and the cells 5a and 5b on the both ends in the direction of the arrow A extend to the direction of the arrow B. For this reason, the both ends of all the strings S are electrically connected in parallel with the first and second power collecting electrodes 6 and 7 via the common second electrode 4.

In a case of FIG. 2(c), the string separating groove 8 completely separates the two adjacent strings S, but all the strings S are electrically connected in parallel by the first and second power collecting electrodes 6 and 7.

The string separating groove 8 includes a first groove 8a formed by removing the first electrode layer 2, and a second groove 8b formed by removing the photoelectric conversion layer 3 and the second electrode layer 4 with its width being wider than that of the first groove 8a. This is preferable for preventing the short circuit between the first electrode layer 2 and the second electrode layer 4 of each cell by means of forming the string separating groove 8. This is described in detail later.

Further, in the string S, the cell 5b on a side of the second power collecting electrode 7 does not practically contribute to the power generation because its width in the series-connecting direction A is narrow. For this reason, the second electrode 4 of the cell 5b is used as an extraction electrode of the first electrode 2 of the adjacent cell 5.

Further, the plurality of strings S are formed on an inner side with respect to an outer peripheral end surface (an end surface of four sides) of the transparent insulating substrate 1. That is to say, an outer peripheral region on the surface of the insulating substrate 1 is a non-conductive surface region 12 that is not formed with the first electrode layer 2, the photoelectric conversion layer 3 and the second electrode layer 4, and its width is set to a dimension range according to an output voltage from the solar battery.

[Transparent Insulating Substrate and First Electrode Layer]

As the transparent insulating substrate 1, a glass substrate, a resin substrate made of polyimide or the like each having a heat-resistant in a subsequent film forming process and transparency.

The first electrode layer 2 is made of a transparent conductive film, and preferably made of a transparent conductive film including a material containing ZnO or SnO₂. The material containing SnO₂ may be SnO₂ itself, or may be a mixture of SnO₂ and another oxide (for example, ITO as a mixture of SnO₂ and In₂O₃).

[Photoelectric Conversion Layer]

A material of each semiconductor layer configuring the photoelectric conversion layer 3 is not particularly limited, and each semiconductor layer includes, for example, a silicon semiconductor, a CIS (CuInSe₂) compound semiconductor, and a CIGS (Cu(In, Ga)Se₂) compound semiconductor.

A case where each semiconductor layer is made of the silicon semiconductor is described as an example below.

“The silicon semiconductor” means a semiconductor made of an amorphous silicon or a microcrystal silicon, or a semiconductor in which carbon, germanium or another impurity is added to an amorphous silicon or a microcrystal silicon (silicon carbide, silicon germanium or the like). Further, “the microcrystal silicon” means a silicon in a state of a mixed phase including a crystal silicon with a small grain size (about several dozens to several thousand Å) and an amorphous silicon. The microcrystal silicon is formed when a crystal silicon thin film is produced at a low temperature by using a nonequilibrium process such as a plasma CVD method.

The photoelectric conversion layer 3 is constituted so that a p-type semiconductor layer, an i-type semiconductor layer and an n-type semiconductor layer are laminated from the side of the first electrode 2. The i-type semiconductor layer may be omitted.

The p-type semiconductor layer is doped with p-type impurity atoms such as boron or aluminum, and the n-type semiconductor layer is doped with n-type impurity atoms such as phosphorus.

The i-type semiconductor layer may be a semiconductor layer that is completely undoped, and, may be a weak p-type or weak n-type semiconductor layer including a small amount of impurities that sufficiently has a photoelectric converting function.

In this specification, “the amorphous layer” and “the microcrystal layer” mean amorphous and microcrystal semiconductor layers, respectively.

Further, the photoelectric conversion layer 3 may be of a tandem type where a plurality of pin structures are laminated. The photoelectric conversion layer 3 may include, for example, an upper semiconductor layer where an a-Si:H p-layer, an a-Si:H i-layer and an a-SiH n-layer are laminated on the first electrode 2 in this order, and a lower semiconductor layer where a μc-Si:H p-layer, a μc-Si:H i-layer and a μc-Si:H n-layer are laminated on the upper semiconductor layer in this order.

Further, the pin structure may be the photoelectric conversion layer 3 having a three-layered structure including the upper semiconductor layer, a middle semiconductor layer and the lower semiconductor layer. For example, the three-layered structure may be such that an amorphous silicon (a-Si) is used for the upper and middle semiconductor layers, and a microcrystal silicon (μc-Si) is used for the lower semiconductor layer.

A combination of the material of the photoelectric conversion layer 3 and the laminated structure is not particularly limited.

In embodiments and examples of the present invention, a semiconductor layer positioned on a light incident side of the thin-film solar battery is the upper semiconductor layer, and a semiconductor layer positioned on a side opposite to the light incident side is the lower semiconductor layer. A straight line drawn in the photoelectric conversion layer 3 in FIGS. 2(a) to (c) shows a boundary between the upper semiconductor layer and the lower semiconductor layer.

[Second Electrode Layer]

A structure and a material of the second electrode layer 4 are not particularly limited, but in one example, the second electrode 4 has a laminated structure where a transparent conductive film and a metal film are laminated on the photoelectric conversion layer.

The transparent conductive film is made of ZnO, ITO, SiO₂ or the like. The metal film is made of metal such as silver or aluminum.

The second electrode layer 4 may be made of only a metal film of Ag or Al, but it is preferable that the transparent conductive film made of ZnO, ITO or SnO₂ is arranged on the side of the photoelectric conversion layer 3 because a reflection rate at which light unabsorbed by the photoelectric conversion layer 3 is reflected from the rear electrode layer 4 is improved, and the thin-film solar battery with high conversion efficiency can be obtained.

[Another Structure]

As not shown, but in this solar battery, a rear surface sealing material is laminated on the transparent insulating substrate 1 via an adhesive layer so as to completely cover the string S and a nonconductive surface region 8.

As the adhesive layer, for example, a sealing resin sheet made of ethylene-vinyl acetate copolymer (EVA) can be used.

As the rear surface sealing material, for example, a laminated film where an aluminum film is sandwiched by a PET film can be used.

Small holes for leading front ends of extraction lines to be connected to the respective power collecting electrodes to the outside are formed on the adhesive layer and the rear surface sealing material in advance.

A terminal box having output lines and terminals to be electrically connected to extraction lines 13 is mounted onto the rear surface sealing material.

Further, a frame (made of, for example, aluminum) is attached to an outer peripheral portion of the solar battery sealed by the rear surface sealing material and the adhesive layer.

<Method for Manufacturing the Integrated Thin-Film Solar Battery>

The integrated thin-film solar battery can be manufactured by a manufacturing method including:

a depositing step of forming a string before division, where the plurality of thin-film photoelectric conversion elements 5 obtained by laminating the first electrode layer 2, the photoelectric conversion layer 3 and the second electrode layer 4 on one surface of the transparent insulating substrate 1 in this order are electrically connected in series to each other;

a film removing step of removing portions of the thin-film photoelectric conversion elements formed on the outer periphery on one surface of the insulating substrate 1 and a predetermined portion of the string before division by means of a light beam and forming the nonconductive surface region 12 and the string separating grooves 8 so as to form a plurality of strings S; and

a power collecting electrode jointing step of electrically jointing the first power collecting electrode 6 and the second power collecting electrode 7 onto at least the second electrode layer 4 of the cells 5a and 5b on the both ends in the series-connecting direction A on the plurality of strings S.

[Depositing Step]

At the depositing step, a transparent conductive film with a thickness of 600 to 1000 nm is formed on an entire surface of the transparent insulating substrate 1 by a CVD method, a sputtering method, a vapor deposition method or the like, and the transparent conductive film is partially removed by a light beam. Thus, a plurality of parallel electrode separating lines 10 that extends to the direction of the arrow B are formed, so that the first electrode layer 2 is formed into a predetermined pattern. At this time, a fundamental wave of a YAG laser (wavelength: 1064 nm) is emitted from a side of the transparent insulating substrate 1 so that the transparent conductive film is separated into a strip shape with a predetermined width, and the plurality of electrode separating lines 10 are formed at predetermined intervals.

Thereafter, the obtained substrate is ultrasonically cleaned by pure water, and the photoelectric conversion film is formed on the first electrode layer 2 by p-CVD so as to completely embed the electrode separating lines 10. For example, an a-Si:H p-layer, an a-Si:H i-layer (film thickness: about 150 nm to 300 nm) and an a-Si:H n-layer are laminated on the first electrode 2 in this order so that the upper semiconductor layer is formed. A μc-Si-H p-layer, a μc-Si:H i-layer (film thickness: about 1.5 μm to 3 μm) and a μc-Si:H n-layer are laminated on the upper semiconductor layer in this order so that the lower semiconductor layer is formed.

Thereafter, the photoelectric conversion film having the tandem structure is partially removed by a light beam, and groove-shaped contact lines for forming the conductive sections 4a, 11a and 11b are formed, so that the photoelectric conversion layer 3 having a predetermined pattern is formed. At this time, a second harmonic of a YAG laser (wavelength: 532 nm) is emitted from the side of the transparent insulating substrate 1, so that the photoelectric conversion film is separated into a strip shape with a predetermined width. Instead of the second harmonic of the YAG laser, a second harmonic of a YVO₄ laser (wavelength: 532 nm) may be used as the laser.

A conductive film is formed on the photoelectric conversion layer 3 by the CVD, sputtering or vapor deposition method so as to completely embed the contact lines, and the conductive film and the photoelectric conversion layer 3 are partially removed by a light beam so that the element separating groove 9 and the second electrode layer 4 having a predetermined pattern is formed. As a result, the strings before division where the plurality of cells 5 on the transparent insulating substrate 1 are electrically connected in series by the conductive sections 4a are formed (see FIG. 2(a)).

In the strings before division, in the cell 5a on the uppermost-stream side, the first and second electrode layers 2 and 4 are short-circuited by the conductive section 11a formed on the lower-stream side near the first power collecting electrode 6 in advance. Further, the first electrode 2 of the cell 5b on the lowermost-stream side and the second electrode layer 4 are short-circuited by the conductive section 11b.

At this time, since the string before division is not yet split into a plurality of them, one cell extends long to the direction of the arrow B.

At this step, the conductive film can be provided with a two-layered structure including the transparent conductive film (ZnO, ITO, SnO₂ or the like) and the metal film (Ag, Al or the like). A film thickness of the transparent conductive film can be 10 to 200 nm, and a film thickness of the metal film can be 100 to 50 nm.

Further, in patterning of the second electrode layer 4, in order to avoid damage to the first electrode layer 2 due to a light beam, a second harmonic of an YAG laser or a second harmonic of the YVO₄ laser that has high permeability with respect to the first conductive layer 2 is emitted from the side of the transparent insulating substrate 1, and the conductive film is separated into a strip pattern with a predetermined width so that the element separating grooves 9 are formed. At this time, processing conditions are preferably selected so that the damage to the first electrode layer 2 is suppressed to minimum, and generation of a burr on a processed silver electrode on the second electrode layer 4 is suppressed.

[Film Removing Step]

After the depositing step, the first electrode layer 2, the photoelectric conversion layer 3 and the second electrode layer 4 as the thin-film photoelectric conversion element portions formed on the outer periphery on the surface of the transparent insulating substrate 1 are removed by a predetermined width of the inner side from the outer periphery end surface of the transparent insulating substrate 1 by using a fundamental wave of the YAG laser. As a result, the nonconductive surface region 12 is formed on the entire periphery of the transparent insulating substrate 1.

Further, after or before this step, in order to divide the string before division into a plurality of them, the cell portions to be divided portions are removed so that a plurality of string separating grooves 8 are formed.

At this time, the fundamental wave of the YAG laser (wavelength: 1064 nm) is emitted from the side of the transparent insulating substrate 1, and the first electrode layer 2, the photoelectric conversion layer 3 and the second electrode layer 4 are partially removed so that the first grooves 8a are formed. Thereafter, the second harmonic of the YAG laser or the second harmonic of the YVO₄ laser that have high permeability with respect to the first conductive layer 2 is emitted from the side of the transparent insulating substrate 1, and the photoelectric conversion layer 3 and the second electrode 4 are partially removed by a width wider than that of the first groove 8a. Second grooves 8b are formed so that the string separating grooves 8 can be formed.

When the second grooves 8b wider than the first grooves 8a are formed later, a conductive material that scatters due to the formation of the first grooves 8a and adheres to groove inner surfaces can be removed, so that the short-circuit between the first electrode layer 2 and the second electrode layer 4 can be avoided.

At the film removing step, plural rows of strings S surrounded by the nonconductive surface region 12 are formed. When the string before division is not divided, only a laser machining for forming the nonconductive surface region 12 is carried out at the film removing step.

[Power Collecting Electrode Jointing Step]

A brazing filler metal (for example, a silver paste) is applied onto the second electrode layer 4 on both ends of the series-connecting direction A in the strings S, the first and second power collecting electrodes 6 and 7 are press-bonded to the brazing filler metal and are then heated. The first and second power collecting electrodes 6 and 7 are electrically connected to the second electrode layer 4, so that an extraction section for an electric current is formed. At this time, as a pressure is, for example, about 60 N, and a heat energy of the heating is, for example, about 30° C. However, since the cells 5a and 5b are thin, the short-circuit portion is occasionally formed on the portions just below the first and the second power collecting electrodes 6 and 7.

Thereafter, the extraction lines 13 are brazed to predetermined portions of the first and second power collecting electrodes 6 and 7.

[Other Steps]

A transparent EVA sheet as adhesive layer and a rear surface sealing material are laminated on the rear surface (non-light receiving surface) of the solar battery, and the rear surface sealing material is bonded to the solar battery via the adhesive layer and is sealed by using a vacuum laminating device. At this time, as the rear surface sealing material, a laminated film where an Al film is sandwiched by PET films is preferably used.

Thereafter, the extraction lines 13 are electrically connected to the output lines of the terminal box, the terminal box is bonded to the rear surface sealing material, and the terminal box is filled with a silicone resin. A metal frame (for example, an aluminum frame) is attached to the outer periphery of the thin-film solar battery, so that a product is finished.

<Power Generating Operation of Integrated Thin-Film Solar Battery>

In the integrated thin-film solar battery according to the embodiment 1 having the above constitution, when light enters the transparent insulating substrate 1 as a light receiving surface, an electromotive force generated on the photoelectric conversion layer 3 of the cells 5 flows in the current direction E, and a direct current extracted from the second power collecting electrode 7 passes through an outside circuit so as to return to the first power collecting electrode 6.

In this case, in the cell 5a jointed to the first power collecting electrode 6, the second electrode layer 4 and the first electrode layer 2 are short-circuited on the portion just below the first power collecting electrode 6, and the electrode separating lines 10 are formed on the lower-stream sides of the conductive sections 11a. For this reason, the cell 5a does not contribute to the power generation, and a portion on a lower-stream side with respect to the electrode separating lines 10 becomes a power generating region so that an electric current flow to this region.

If the conductive section 11a is not present in the cell 5a and the removal of the transparent conductive film at the time of forming the electrode separating lines 10 is not sufficient, an electric current might flow also to the short-circuited portion just below the first power collecting electrode 6 and a heat might be generated.

For this reason, in order to prepare for such a case, in the solar battery according to the embodiment 1, the first electrode layer 2 and the second electrode layer 4 are short-circuited by the conductive section 11a in advance so that an electric current does not flow to the short-circuited portion of the cell 5a jointed to the first power collecting electrode 6. This prevents a local heat generation in advance.

Further, in the cell 5b jointed to the second power collecting electrode 7, an electric current flow from the first electrode layer 2 of the cell 5 on the upper-stream side to the second electrode layer 4 of the cell 5b via the conductive section 4a, and the electric current is extracted from the second power collecting electrode 7.

Since the first electrode layer 2 of the cell 5b is insulated and separated from the first electrode layer 2 of the cell 5 on the upper-stream side by the electrode separating lines 10, an electric current does not flow thereto. However, if the removal of the transparent conductive film at the time of forming the electrode separating lines 10 is not sufficient, an electric current flow to the first electrode layer 2 of the cell 5b, and the electric current might flow to the short-circuited portion of the photoelectric conversion layer 3. In this case, a heat might be generated from the short-circuited portion due to the electric current.

For this reason, in order to prepare for such a case, in the solar battery according to the embodiment 1, the first electrode layer 2 and the second electrode layer 4 are short-circuited in advance by the conductive section 11b so that an electric current does not flow to the short-circuited portion of the cell 5b jointed to the second power collecting electrode 7 on a current extracting side, thereby preventing the local heat generation.

### Embodiment 2

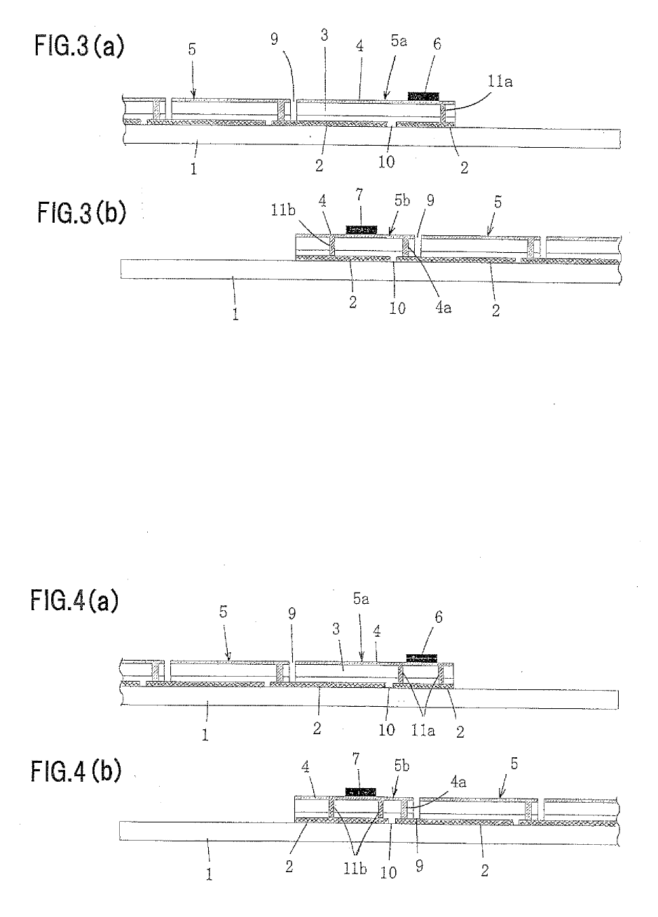

FIG. 3 is a cross-sectional view illustrating the integrated thin-film solar battery according to an embodiment 2 of the present invention, FIG. 3(a) illustrates a side of the first power collecting electrode, and FIG. 3(b) illustrates a side of the second power collecting electrode. Components in FIG. 3 are denoted by the same reference symbols as those of the components in FIGS. 1 and 2.

A different point of the embodiment 2 from the embodiment 1 is only positions of the conductive sections 11a and 11b of the cells 5a and 5b jointed to the first and second power collecting electrodes 6 and 7, respectively.

That is to say, in a case of the embodiment 2, the conductive section 11a is arranged on the upper-stream side in the current direction E with respect to the first power collecting electrode 6 of the cell 5a, and the conductive section 11b is arranged on the lower-stream side with respect to the second power collecting electrode 7 of the cell 5b.

Also in this constitution, similarly to the embodiment 1, the local heat generation on the short-circuited portions just below the first and second power collecting electrodes 6 and 7 is prevented. The other parts of the constitution in the embodiment 2 are similar to those in the embodiment 1.

### Embodiment 3

FIG. 4 is a cross-sectional view illustrating the integrated thin-film solar battery according to an embodiment 3 of the present invention, FIG. 4(a) illustrates the side of the first power collecting electrode, and FIG. 4(b) illustrates the side of the second power collecting electrode. Components in FIG. 4 are denoted by the same reference symbols as those in the components in FIGS. 1 and 2.

In a case of the embodiment 3, the conductive section 11a of the cell 5a is arranged on the upper-stream side and the lower-stream side of the first power collecting electrode 6, and the conductive section 11b of the cell 5b is arranged on the upper-stream side and the lower-stream side of the second power collecting electrode 7.

In such a constitution, the first electrode layer 2 and the second electrode layer 4 just below and near the first and second power collecting electrodes 6 and 7 can be short-circuited more securely in the cells 5a and 5b. Further, since damage to the conductive section for the short-circuit can be suppressed even when particularly a large electric current flow, the heat generation on the short-circuited portions just below the first and second power collecting electrodes 6 and 7 is prevented more effectively. The other parts of the constitution in the embodiment 3 are similar to those in the embodiment 1.

### Embodiment 4

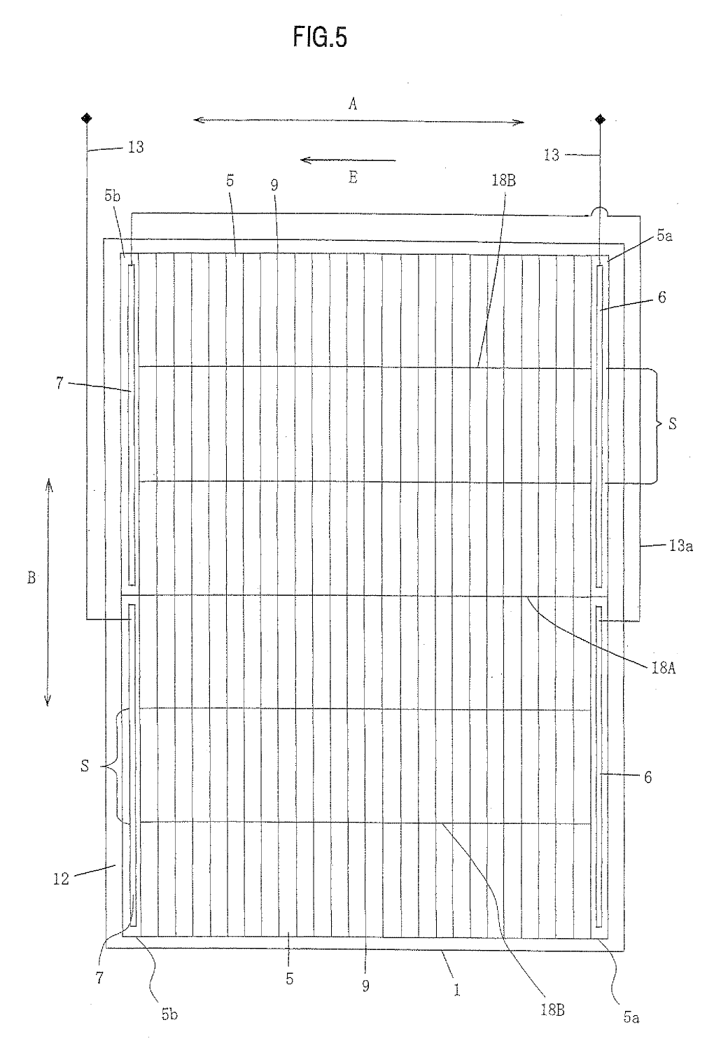

FIG. 5 is a plan view illustrating the integrated thin-film solar battery according to an embodiment 4 of the present invention. Components in FIG. 5 are denoted by the same reference symbols as those of the components in FIGS. 1 and 2.

In the solar battery according to the embodiment 4, a plurality of the strings S are arranged on the one transparent insulating substrate 1 in the direction B perpendicular to the series-connecting direction A across one or more string separating grooves extending to the series-connecting direction. Further, at least one string separating groove completely insulates and separates the plurality of strings S according to each group. Further, the plurality of strings S in each group are electrically connected in parallel by the first power collecting electrode 16 and the second power collecting electrode 17, and a plurality of groups are electrically connected in series.

More specifically, in a case of the embodiment 4, the six strings S are formed on the one insulating substrate 1, and a first group including the three adjacent strings S and a second group including the other adjacent three strings S are completely insulated and separated by one string separating groove 18A.

Each string separating groove 18B in each group does not completely separate the adjacent two strings S, and the cells 5a and 5b on the both ends in the series-connecting direction A in the three strings S in each group are integrated with each other. The first and second power collecting electrodes 6 and 7 are individually jointed onto the integrated cells 5a and 5b.

Therefore, the three strings S in each group are electrically connected in parallel, but the first group and the second group are not electrically connected in parallel.

In the solar battery having such a constitution, the first power collecting electrode 6 in the first group and the second power collecting electrode 7 in the second group are electrically connected in series by the extraction line 13a directly or via a connection to the connecting line provided to the terminal box. The residual first and second power collecting electrodes 6 and 7 are electrically connected to the output lines of the terminal box via the extraction lines 13.

According to the embodiment 4, since electric currents generated in the first group and the second group flow in the current direction E and the first group and the second group are electrically connected in series, the embodiment 4 is effective for providing the constitution where one solar battery outputs a high-voltage current.

In the embodiment 4, the other parts and effect of the constitution are similar to those in the embodiment 1, and a local heat generation is prevented on the short-circuited portions just below the first and second power collecting electrodes 6 and 7.

### Embodiment 5

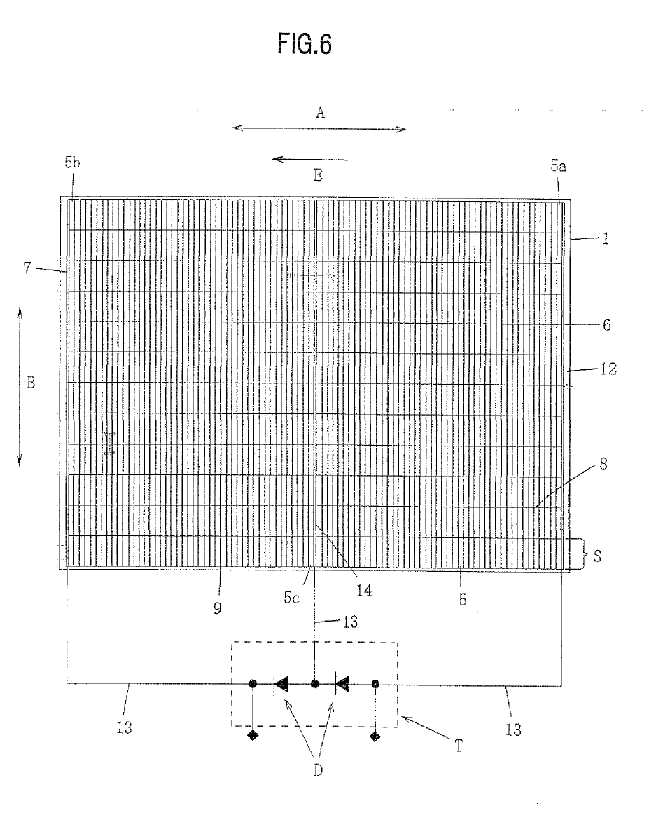

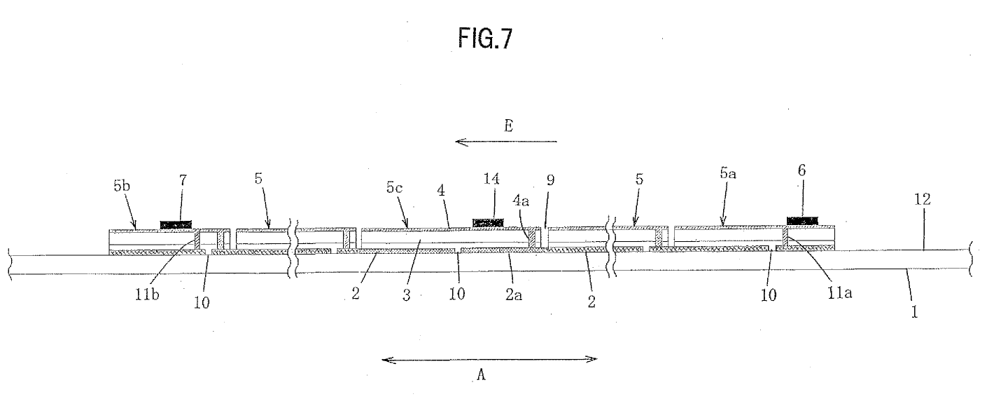

FIG. 6 is a plan view illustrating the integrated thin-film solar battery according to an embodiment 5 of the present invention, and FIG. 7 is a cross-sectional view where the integrated thin-film solar battery in FIG. 6 is cut along the series-connecting direction. Components in FIGS. 6 and 7 are denoted by the same reference symbols as those of the components in FIGS. 1 and 2.

A different point of the embodiment 5 from the embodiment 1 are the following two points.

The first point is that an intermediate power collecting electrode 14 is formed on the second electrode layer 4 of one or more cell(s) 5c between the cells 5a and 5b on the both ends having the first power collecting electrode 6 and the second power collecting electrode 7.

The second point is that the electrode separating lines 10 are arranged on the lower-stream side of the current direction E with respect to the portion just below the intermediate power collecting electrode 14 in the cell 5c having the intermediate power collecting electrode 14.

Concretely, in the solar battery, similar to the embodiment 1, the twelve strings S are arranged in parallel on the one transparent insulating substrate 1 across the string separating grooves 8, and the first and second power collecting electrodes 6 and 7 are jointed onto the cells 5a and 5b of the respective strings S on the upper-stream side and the lower-stream side in the current direction E. The respective strings S are electrically connected in parallel.

Further, the one intermediate power collecting electrode 14 is jointed onto the cell 5c on an approximate middle position of each string S in the series-connecting direction A via a brazing filler metal (for example, a silver paste).

The respective cells 5c to be jointed to the intermediate power collecting electrode 14 are separated from each other by the string separating grooves 8 as shown in FIG. 2(c), but may be connected integrally as shown in FIG. 2(b).

As shown in FIG. 7, in the cells 5c having the intermediate power collecting electrode 14, the electrode separating line 10 is arranged on a position slightly shifted to the lower-stream side of the current direction E with respect to the portion just below the intermediate power collecting electrode 14. That is to say, the extending section 2a of the first electrode layer 2 of the cells 5 positioned on the upper-streams side of the cells 5c in the current direction E extends to the lower-stream side with respect to the portion just below the intermediate power collecting electrode 14.

Further, the electrode separating line 10a is formed on the lower-stream side of the conductive section 11a of the first electrode layer 2 in the cell 5a on the uppermost-stream side.

In the solar battery according to the embodiment 5 having such a constitution, as shown in FIG. 6, the plurality of strings S are electrically connected in parallel by the first power collecting electrode 6, the intermediate power collecting electrode 14 and the second power collecting electrode 7. Further, a plurality of bypass diodes D provided into the terminal box T are electrically connected in parallel via the extraction lines 13 in the plurality of strings S electrically connected in parallel, and the plurality of bypass diodes D are electrically connected in series.

With such a connection, the integrated thin-film solar battery, that provides a high-voltage output while a hot spot resistance is being maintained, can be obtained.

In the embodiment 5, the parts other than such a constitution are similar to those in the embodiment 1, and the manufacturing can be carried out according to the manufacturing method in the embodiment 1.

A power generating operation of the solar battery according to the embodiment 5 is basically the same as that in the embodiment 1, but in the cells 5c to which the intermediate power collecting electrode 14 is jointed, the power generating operation is as follows.

In the cells 5c jointed to the intermediate power collecting electrode 14, an electric current flow from the first electrode layer 2 of the cells 5 on the upper-stream side to the second electrode layer 4 of the cells 5c via the conductive section 4a. Most part of the electric current is extracted from the intermediate power collecting electrode 14, and a part of the electric current passes through the photoelectric conversion layer 3 so as to flow to the first electrode layer 2 on the lower-stream side with respect to the electrode separating lines 10.

Therefore, in the cells 5c jointed to the intermediate power collecting electrode 14, even when the short-circuited portion is present in the photoelectric conversion layer 3 just below the intermediate power collecting electrode 14, a local heat generation due to application of the electric current to the short-circuited portion hardly occurs. Further, even when an electric current is generated in the photoelectric conversion layer 3 just below the intermediate power collecting electrode 14, there is no danger in flowing of the electric current to the short-circuited portion and the heat generation on that portion.

### Embodiment 6

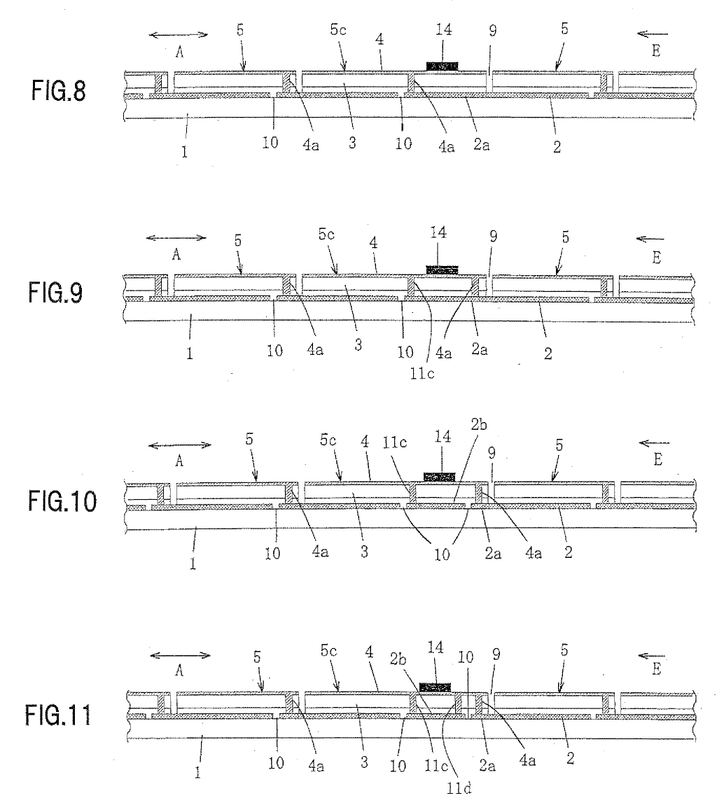

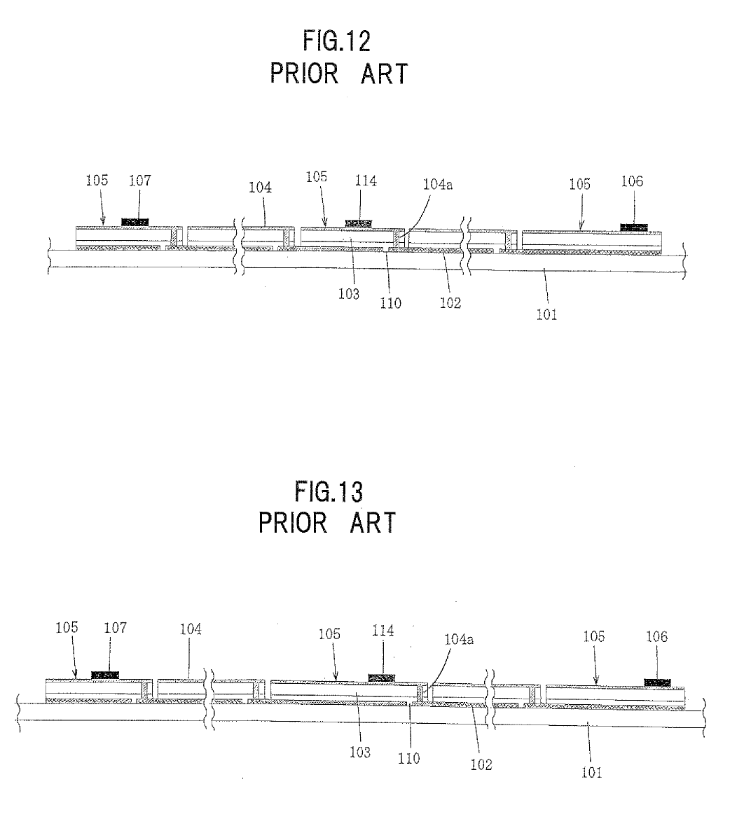

FIG. 8 is a partial cross-sectional view illustrating the integrated thin-film solar battery according to an embodiment 6 of the present invention. Components in FIG. 8 are denoted by the same reference symbols as those of the components in FIGS. 6 and 7.

In a case of the embodiment 6, the conductive sections 4a of the cells 5c jointed to the intermediate power collecting electrode 14 are arranged on the lower-stream side of the intermediate power collecting electrode 14, and the parts other than this are similar to those in the embodiment 5.

Even with such a constitution, similar to the embodiment 5, the local heat generation on the short-circuited portion just below the intermediate power collecting electrode 14 is prevented.

### Embodiment 7

FIG. 9 is a partial cross-sectional view illustrating the integrated thin-film solar battery according to an embodiment 7 of the present invention. Components in FIG. 9 are denoted by the same reference symbols as those of the components in FIGS. 6 and 7.

In a case of the embodiment 7, in the cells 5c to which the intermediate power collecting electrode 14 is jointed, conductive sections 4a and 11c are arranged on two places on the upper-stream side and the lower-stream side of the intermediate power collecting electrode 14, and the other parts of the constitution are similar to those in the embodiment 5.

With such a constitution, similar to the embodiment 5, the local heat generation on the short-circuited portion just below the intermediate power collecting electrode 14 is prevented, and the second electrode layer 4 of the cells 5c to which the intermediate power collecting electrode 14 and the first electrode layer 2 of the cells 5 on the upper stream side can be short-circuited (connected in series) more securely on the upper-stream side and the lower-stream side of the intermediate power collecting electrode 14. Even when a large electric current flow, damage to the conductive sections can be suppressed.

### Embodiment 8

FIG. 10 is a partial cross-sectional view illustrating the integrated thin-film solar battery according to an embodiment 8 of the present invention. Components in FIG. 10 are denoted by the same reference symbols as those of the components in FIGS. 6 and 7.

In the cells 5c jointed to the intermediate power collecting electrode 14, a different point of the embodiment 8 from the embodiment 7 is that one more electrode separating line 10 is formed on the lower-stream side with respect to the conductive section 4a on the upper stream side and is on the upper-stream side with respect to the intermediate power collecting electrode 14. The other parts of the constitution are similar to those in the embodiment 7.

With such a constitution, the first electrode layer 2 just below and near the intermediate power collecting electrode 14 can be insulated and separated by the electrode separating lines 10 on the both sides, namely, the portions just below and near the intermediate power collecting electrode 14 in the cells 5c can be independent from the path of an electric current.

Therefore, even when the short-circuited portion is formed just below the intermediate power collecting electrode 14 of the cells 5c, a large electric current does not flow thereto, and thus the local heat generation on the short-circuited portions is prevented.

### Embodiment 9

FIG. 11 is a partial cross-sectional view illustrating the integrated thin-film solar battery according to an embodiment 9 of the present invention. Components in FIG. 11 are denoted by the same reference symbols as those of the components in FIG. 10.

A different point of the embodiment 9 from the embodiment 8 is that a third conductive section 11d is formed in the cells 5c jointed to the intermediate power collecting electrode 14, on the lower-stream side with respect to the electrode separating line 10 on the upper-stream side and on the upper-stream side with respect to the intermediate power collecting electrode 14. The other parts of the constitution are similar to those in the embodiment 7.

Even with such a constitution, similar to the embodiment 8, the heat generation on the short-circuited portion just below the intermediate power collecting electrode 14 is prevented, and the insulated and separated first electrode layer 2 just below the intermediate power collecting electrode 14 is short-circuited from the second electrode layer 4 more securely. For this reason, the effect for preventing the local heat generation is further heightened.

### Another Embodiment

The number of the strings, the attachment positions and the number of the power collecting electrodes are not limited to the above embodiments. For example, the intermediate power collecting electrode is left, and the first and second power collecting electrodes on the both ends in the series-connecting direction may be connected to the first electrode layer (p-side electrode, n-side electrode).

Further, the intermediate power collecting electrode may be provided to a plurality of places in the series-connecting direction of the strings.

Further, a number of string forming regions on one transparent insulating substrate is four, and a group of the strings is formed on each region, and a plurality of groups may be connected into a desired form.

### DESCRIPTION OF REFERENCE SYMBOLS

1: transparent insulating substrate
2: transparent first electrode layer
3: photoelectric conversion layer
4: second electrode layer
4a, 11a, 11b, 11c, 11d: conductive section
5, 5a, 5b, 5c: thin-film photoelectric conversion element (cell)
6: first power collecting electrode
7: second power collecting electrode
8, 18A, 18B: string separating groove
9: element separating groove
2a: extending section
10: electrode separating line
14: intermediate power collecting electrode
A: series-connecting direction
B: direction perpendicular to the series-connecting direction
D: bypass diode
E: current direction
S: string

1. An integrated thin-film solar battery, comprising:
a string that includes a plurality of thin-film photoelectric conversion elements formed on a transparent insulating substrate and electrically connected in series to each other; and
one or more power collecting electrodes electrically jointed to the string, wherein
the thin-film photoelectric conversion elements have a first transparent electrode layer laminated on the transparent insulating substrate, a photoelectric conversion layer laminated on the first electrode layer, and a second electrode layer laminated on the photoelectric conversion layer,
the power collecting electrode is electrically jointed onto the second electrode layer of any thin-film photoelectric conversion element in the string,
the string has an element separating groove formed by removing the second electrode layer and the photoelectric conversion layer between the adjacent two thin-film photoelectric elements,
the first electrode layer of one thin-film photoelectric conversion element has an extending section whose one end crosses the element separating groove and that extends to a region of another adjacent thin-film photoelectric conversion element, and is electrically insulated from the first electrode layer of the adjacent thin-film photoelectric conversion element by one or more electrode separating line,
the second electrode layer of the one thin-film photoelectric conversion element is electrically connected to the extending section of the first electrode layer of the adjacent thin-film photoelectric conversion element via a conductive section passing through the photoelectric conversion layer,
the thin-film photoelectric conversion element jointed to the power collecting electrode is constituted so that the conductive section is arranged on at least one of an upper-stream side and a lower-stream side in a current direction of an electric current flowing through the string with respect to the power collecting electrode, and the first electrode layer just below and near the power collecting electrode is short-circuited from the second electrode layer by the one or more conductive sections.

2. The integrated thin-film solar battery according to claim 1, wherein the conductive section is made of a same material as that of the second electrode.

3. The integrated thin-film solar battery according to claim 1, wherein the power collecting electrode includes a first power collecting electrode and a second power collecting electrode, and the first power collecting electrode and the second power collecting electrode are jointed onto the second electrode layer of two thin-film photoelectric conversion elements on both ends in a series-connecting direction in the string.

4. The integrated thin-film solar battery according to claim 3, wherein the power collecting electrode includes one or more intermediate power collecting electrodes, and the intermediate power collecting electrodes are jointed onto the second electrode layer of one or more thin-film photoelectric conversion elements between the two thin-film photoelectric conversion elements on the both ends in the series-connecting direction in the string.

5. The integrated thin-film solar battery according to claim 4, wherein in the thin-film photoelectric conversion element jointed to the intermediate power collecting electrode, the electrode separating line is formed at the first electrode layer on an upper-stream vicinity portion and a lower-stream vicinity portion just below the intermediate power collecting electrode so that portions of the first electrode layer just below and near the intermediate power collecting electrode are insulated and separated from each other.

6. The integrated thin-film solar battery according to claim 1, wherein in the thin-film photoelectric conversion element jointed to the power collecting electrode, the electrode separating line is formed on at least one of the upper-stream side and the lower-stream side with respect to the power collecting electrode.

7. The integrated thin-film solar battery according to claim 1, wherein
a plurality of the strings are arranged on the one transparent insulating substrate in a direction perpendicular to the series-connecting direction across one or more string separating grooves extending to the series-connecting direction,
the plurality of strings are electrically connected in parallel or in series.

8. The integrated thin-film solar battery according to claim 3, wherein
a plurality of the strings are arranged on the one transparent insulating substrate in a direction perpendicular to the series-connecting direction across one or more string separating grooves extending to the series-connecting direction,
the plurality of strings are completely insulated and separated into a plurality of groups by at least one string separating groove,
the plurality of strings in each group are electrically connected in parallel by the first power collecting electrode and the second power collecting electrode,
the plurality of groups are electrically connected in series.

9. The integrated thin-film solar battery according to claim 8, wherein in each group including the plurality of strings, the plurality of thin-film photoelectric conversion elements that are positioned on both ends in the series-connecting direction and is adjacent in the direction perpendicular to the series-connecting direction is connected integrally without being separated by the string separating grooves.

10. The integrated thin-film solar battery according to claim 4, wherein
a plurality of the strings are arranged in parallel on the one transparent insulating substrate in a direction perpendicular to the series-connecting direction across one or more string separating grooves extending to the series-connecting direction,
the plurality of strings are electrically connected in parallel by the first power collecting electrode, the intermediate power collecting electrode and the second power collecting electrode,
a plurality of bypass diodes are electrically connected in parallel to the plurality of strings electrically connected in parallel,
the plurality of bypass diodes are electrically connected in series.

11. The integrated thin-film solar battery according to claim 10, wherein in the plurality of strings, the plurality of thin-film photoelectric conversion elements that are positioned on the both ends of the series-connecting direction and is adjacent in the direction perpendicular to the series-connecting direction is connected integrally without being separated by the string separating grooves.

12. The integrated thin-film solar battery according to claim 7, wherein the string separating groove includes a first groove formed by removing the first electrode layer, and a second groove formed by removing the photoelectric conversion layer and the second electrode layer by a width larger than a width of the first groove.
